(19) United States
(12) Patent Application Publication
(10) Pub. No.: US 2026/0372151 A1
(43) Pub. Date: Nov. 19, 2026

(54) BONDING TOOL AND CHIP-on-WAFER BONDING PROCESS

(71) Applicant: Taiwan Semiconductor Manufacturing Company, Ltd., Hsinchu (TW)

(72) Inventors: Ming-Tsu Chung, Hsinchu City (TW); Yung-Chi Lin, New Taipei City (TW); Yan-Zuo Tsai, Hsinchu City (TW); Yang-Chih Hsueh, Hsinchu City (TW)

(73) Assignee: Taiwan Semiconductor Manufacturing Company, Ltd., Hsinchu (TW)

(21) Appl. No.: 19/754,278

(22) Filed: Jul. 27, 2026

Related U.S. Application Data
(62) Division of application No. 18/504,158, filed on Nov. 8, 2023.

(51) Int. Cl. H10W 72/00; H10P 10/00; H10W 80/00; H10W 99/00

(52) U.S. Cl. CPC H10W 72/011; H10P 10/12; H10P 10/128; H10W 72/07173; H10W 99/00; H10W 72/071; H10W 72/07188; H10W 80/041; H10W 80/312; H10W 80/327

(57) ABSTRACT

A bonding tool for bonding semiconductor dies to a semiconductor wafer is provided. The bonding tool includes a wafer chuck, an edge support, a hard plate, and a buffer layer. The wafer chuck carries the semiconductor wafer and the semiconductor dies placed on the semiconductor wafer. The edge support is disposed on the wafer chuck, the semiconductor wafer and the semiconductor dies are laterally surrounded by the edge support, and a top surface of the edge support substantially levels with surfaces of the semiconductor dies. The hard plate is movably disposed over the semiconductor dies, the edge support and the wafer chuck. The buffer layer is disposed on a bottom surface of the hard plate, and the buffer layer is in contact with the top surface of the edge support and the semiconductor dies when the hard plate moves towards the edge support.

### CROSS-REFERENCE TO RELATED APPLICATION

This application is a divisional application of and claims the priority benefit of a prior application Ser. No. 18/504,158, filed on Nov. 8, 2023 and now pending. The entirety of the above-mentioned patent applications is hereby incorporated by reference herein and made a part of this specification.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. These smaller electronic components such as integrated circuit dies may also require smaller and reliable packages that utilize less area than packages of the past, in some applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1D schematically illustrating a chip-on-wafer (CoW) bonding process utilizing a bonding tool in accordance with some embodiments of the present disclosure.

FIG. 2 is a top view schematically illustrating the relationship of the edge support, the semiconductor wafer, the hard plate, and wafer chuck shown in FIG. 1A through FIG. 1D.

FIG. 3A through FIG. 3D schematically illustrating a chip-on-wafer (CoW) bonding process utilizing a bonding tool in accordance with some other embodiments of the present disclosure.

FIG. 4 is a top view schematically illustrating the relationship of the edge support, the semiconductor wafer, the hard plate, and wafer chuck shown in FIG. 3A through FIG. 3D.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

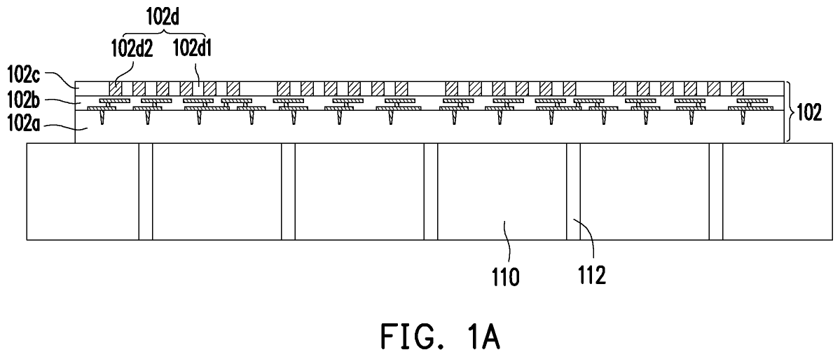

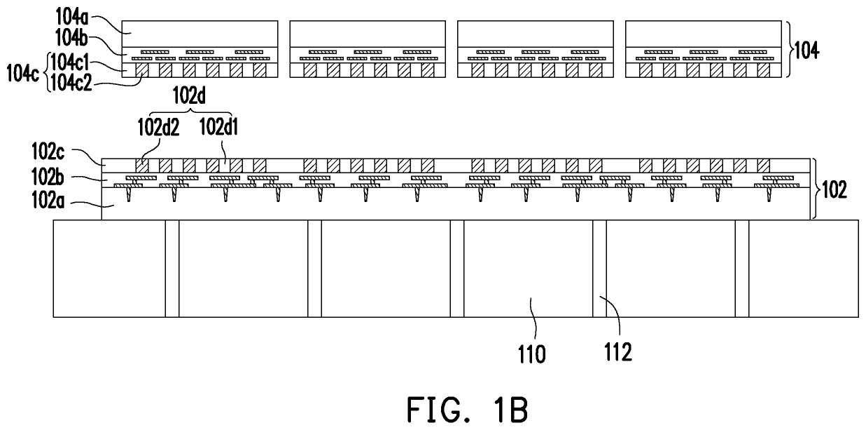

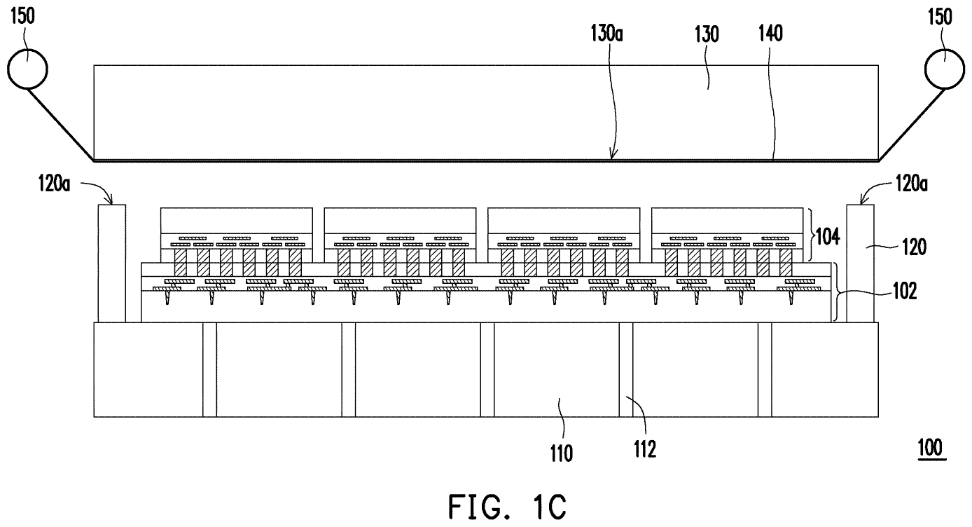

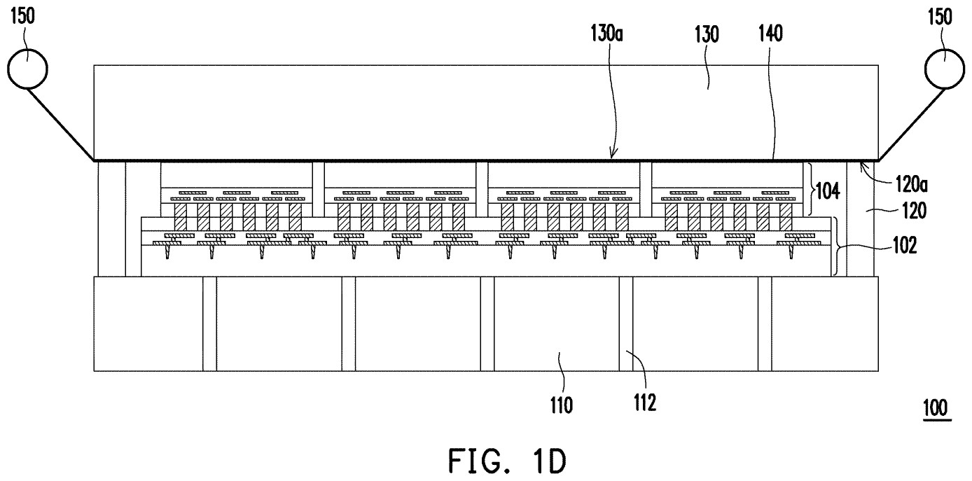

FIG. 1A through FIG. 1D schematically illustrating a chip-on-wafer (CoW) bonding process utilizing a bonding tool in accordance with some embodiments of the present disclosure.

Referring to FIG. 1A, a semiconductor wafer 102 is provided. In some embodiments, the semiconductor wafer 102 includes semiconductor chips arranged in array, and the semiconductor chips in the semiconductor wafer 102 may be logic dies, System-on-Chip (SoC) dies or other suitable semiconductor dies. The semiconductor wafer 102 may include a substrate 102a (e.g., a semiconductor substrate), through substrate vias 102b embedded in the substrate 102a, an interconnect structure 102c disposed on the substrate 102a, and a bonding structure 102d disposed on the interconnect structure 102c, wherein the through substrate vias 102b are electrically connected to the interconnect structure 102c. The substrate 102a of the semiconductor wafer 102 may include a crystalline silicon wafer. The substrate 102a may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 102a may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The through substrate vias 102b may be formed by forming recesses in the substrate 102a by, for example, etching, milling, laser techniques, a combination thereof, and/or the like. A thin barrier layer may be conformally deposited over the front side of the substrate 102a and in the openings, such as by chemical vapor deposition (CVD), atomic layer deposition (ALD), physical vapor deposition (PVD), thermal oxidation, a combination thereof, and/or the like. The barrier layer may include a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the substrate 102a by, for example, chemical mechanical polishing (CMP). Thus, in some embodiments, the through substrate vias 102b may include a conductive material and a thin barrier layer between the conductive material and the substrate 102a. In some embodiments, the through substrate vias 102b may extend through one or more layers of the interconnect structure 102b and protrude into the substrate 102a. The through substrate vias 102b may be buried in the substrate 102a and the interconnect structure 102c of the semiconductor wafer 102. The through substrate vias 102b are not revealed from a back surface of the substrate 102a at this stage.

The interconnect structure 102c may include one or more dielectric layers (for example, one or more interlayer dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the substrate 102a. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof.

The bonding structure 102d may include a bonding dielectric layer 102d1 and bonding conductors 102d2 embedded in the bonding dielectric layer 102d1. The material of the bonding dielectric layer 102d1 may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 102d2 may be conductive vias (e.g., copper vias), conductive pads (e.g., copper pads) or combinations thereof. The bonding structure 102d may be formed by depositing a dielectric material through a chemical vapor deposition (CVD) process (e.g., a plasma enhanced CVD process or other suitable process); patterning the dielectric material to form the bonding dielectric layer 102d1 including openings or through holes; and filling conductive material in the openings or through holes defined in the bonding dielectric layer 102d1 to form the bonding conductors 102d2 embedded in the bonding dielectric layer 102d1.

In some other embodiments, the semiconductor wafer 102 includes a semiconductor interposer, such as a silicon interposer or other suitable semiconductor interposer. In some alternative embodiments, the semiconductor wafer 102 includes a reconstructed wafer, and the reconstructed wafer may include semiconductor chips arranged in side-by-side manner and laterally encapsulated by an insulating encapsulant.

As illustrated in FIG. 1A, the semiconductor wafer 102 is placed on and held by a wafer chuck 110. The wafer chuck 110 may include vacuum suctions 112 communicated with a vacuum extraction machine (not shown) such that the semiconductor wafer 102 can be carried by the wafer chuck 110 stably.

Referring to FIG. 1B, semiconductor dies 104 are provided over the semiconductor wafer 102 carried by the wafer chuck 110. The semiconductor dies 104 and the semiconductor chips in the semiconductor wafer 102 may perform the same function or different functions. In some embodiments, the semiconductor dies 104 and the semiconductor chips in the semiconductor wafer 102 are System on Chip (SoC) dies performing the same function or different functions.

Each of the semiconductor dies 104 may include a substrate 104a (e.g., a semiconductor substrate), an interconnect structure 104b disposed on the substrate 104a, and a bonding structure 104c disposed on the interconnect structure 104b. The substrate 104a of each of the semiconductor dies 104 may include a crystalline silicon wafer. The substrate 104a may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 104a may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The interconnect structure 104b may include one or more dielectric layers (for example, one or more interlayer dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the substrate 104a. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof.

The bonding structure 104c may include a bonding dielectric layer 104c1 and bonding conductors 104c2 embedded in the bonding dielectric layer 104c1. The material of the bonding dielectric layer 104c1 may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 104c2 may be conductive vias (e.g., copper vias), conductive pads (e.g., copper pads) or combinations thereof. The bonding structure 104c may be formed by depositing a dielectric material through a chemical vapor deposition (CVD) process (e.g., a plasma enhanced CVD process or other suitable process); patterning the dielectric material to form the bonding dielectric layer 104c1 including openings or through holes; and filling conductive material in the openings or through holes defined in the bonding dielectric layer 104c1 to form the bonding conductors 104c2 embedded in the bonding dielectric layer 104c1.

Referring to FIG. 1C, through proper alignment, the semiconductor dies 104 are picked-up and placed onto the semiconductor wafer 102. After the semiconductor dies 104 are picked-up and placed onto the semiconductor wafer 102, an edge support 120 is provided on the wafer chuck 110 such that the semiconductor wafer 102 and the semiconductor dies 104 are laterally surrounded by the edge support 120. In some embodiments, the edge support 120 is fastened on the top surface of the wafer chuck 110 through, for example, screws or other suitable fastening elements such that the top surface 120a of the edge support 120 substantially levels the surfaces (e.g., the back surfaces) of the substrate 104a of the semiconductor dies 104. In some embodiments, the edge support 120 includes a ring-shaped support structure, and the edge support 120 is laterally spaced apart from the semiconductor wafer 102 as well as the semiconductor dies 104 placed on the semiconductor wafer 102.

After installation of the edge support 120, a hard plate 130 and a buffer layer 140 carried by the hard plate 130 are provided over the semiconductor dies 104 as well as the semiconductor wafer 102 carried by the wafer chuck 110. The material of the hard plate 130 may be or include polyetheretherketone (PEEK), polyimide or other suitable plastic materials. The buffer layer 140 may be or include a release film or other flexible and buffer film. The buffer layer 140 is provided on a bottom surface 130a of the hard plate 130. After the buffer layer 140 is provided on the bottom surface 130a of the hard plate 130, the buffer layer 140 is provided between the hard plate 130 and the semiconductor dies 104. The buffer layer 140 may be applied or fed by a group of rollers 150 such that the buffer layer 140 can be fed onto the bottom surface 130a of the hard plate 130. The buffer layer 140 is capable of minimizing the Total Thickness Variation (TTV) issue of the semiconductor dies 104 during the subsequently performed Chip-to-Wafer (CoW) bonding process. The group of rollers 150 are capable of driving the movement of the buffer layer 140 such that different regions of the buffer layer 140 can be utilized to minimize the TTV issue of the semiconductor dies 104 during the subsequently performed Chip-to-Wafer (CoW) bonding process.

Referring to FIG. 1C and FIG. 1D, after the semiconductor dies 104 are picked-up and placed onto the semiconductor wafer 102, the hard plate 130 is driven to move towards the edge support 120 and the wafer chuck 110 such that the buffer layer 140 can move downwardly until the buffer layer 140 is in contact with the top surface of the edge support 120 and the surfaces (e.g., the back surfaces) of the semiconductor dies 104. After the buffer layer 140 is pressed onto the top surface of the edge support 120 and the surfaces (e.g., the back surfaces) of the semiconductor dies 104, a gap between the hard plate 130 and the semiconductor wafer 102 is maintained by the edge support 120 disposed under the hard plate 130. For example, the gap between the hard plate 130 and the semiconductor wafer 102 is maintained by the edge support 120 disposed on the wafer chuck 110 after the buffer layer 140 is pressed onto the semiconductor dies 104.

After the buffer layer 140 is pressed onto the top surface of the edge support 120 and the surfaces (e.g., the back surfaces) of the semiconductor dies 104, an annealing process is performed such that the bonding structures 104c of the semiconductor dies 104 are in contact with and bonded to the bonding structure 102d of the semiconductor wafer 102. After performing the annealing process, a chip-to-wafer (CoW) bonding process of the semiconductor dies 104 and the semiconductor wafer 102 is accomplished.

After performing the above-mentioned chip-to-wafer (CoW) bonding process, a dielectric-to-dielectric bonding interface is formed between the bonding dielectric layer 104c1 and the bonding dielectric layer 102d1, and metal-to-metal bonding interfaces are formed between the bonding conductors 104c2 and bonding conductors 102d2.

After the semiconductor dies 104 are bonded to the semiconductor wafer 102, a chip probing process may be performed to increase yields.

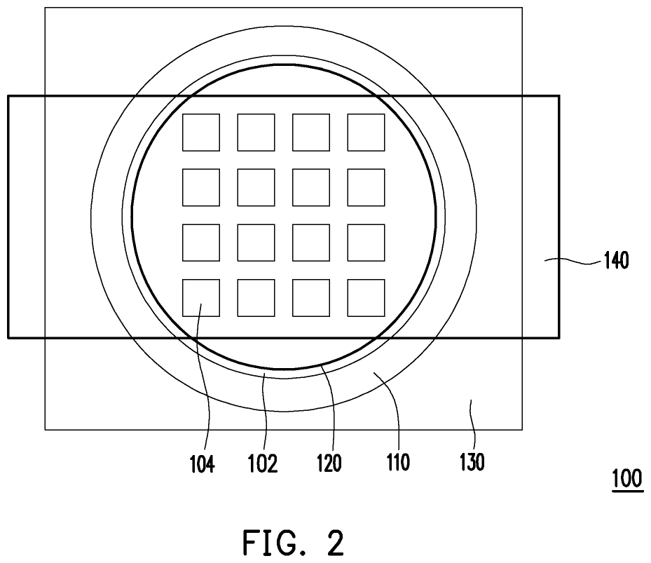

FIG. 2 is a top view schematically illustrating the relationship of the edge support, the semiconductor wafer, the hard plate, and wafer chuck shown in FIG. 1A through FIG. 1D.

As illustrated in FIG. 1C, FIG. 1D and FIG. 2, a bonding tool 100 for bonding semiconductor dies 104 to a semiconductor wafer 102 is provided. The bonding tool 100 of the present embodiment includes a wafer chuck 110, an edge support 120, a hard plate 130, and a buffer layer 140. The wafer chuck 110 carries the semiconductor wafer 102 and the semiconductor dies 104 placed on the semiconductor wafer 102. The edge support 120 is disposed on the wafer chuck 110, the semiconductor wafer 102 and the semiconductor dies 104 are laterally surrounded by the edge support 120, and the top surface 120a of the edge support 120 substantially levels with the surfaces of the semiconductor dies 104. The hard plate 130 is movably disposed over the semiconductor dies 104, the edge support 120 and the wafer chuck 110. The buffer layer 140 is disposed on the bottom surface 130a of the hard plate 130, and the buffer layer 140 is in contact with the top surface 120a of the edge support 120 and the semiconductor dies 104 when the hard plate 130 moves towards the edge support 120. As illustrated in FIG. 2, the wafer chuck 110 may be or include a circular-shaped chuck, and the hard plate 130 may be or include a circular-shaped hard plate. For example, the hard plate includes a circular-shaped hard plate, and the diameter of the ring-shaped support structure 120 is smaller than the diameter of the circular-shaped hard plate 130. Furthermore, the bonding tool 100 may further include a group of rollers 150 for feeding the buffer layer 140 onto the bottom surface 130a of the hard plate 130.

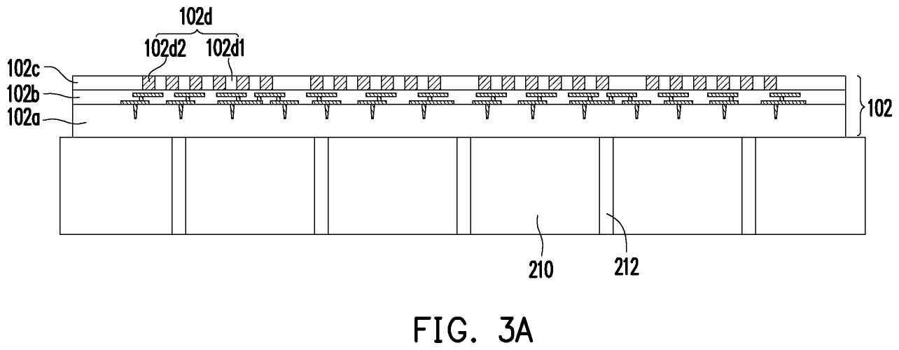

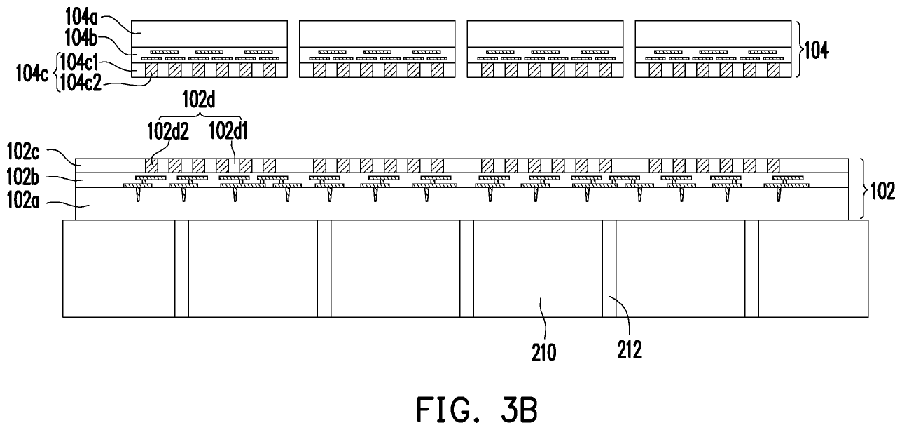

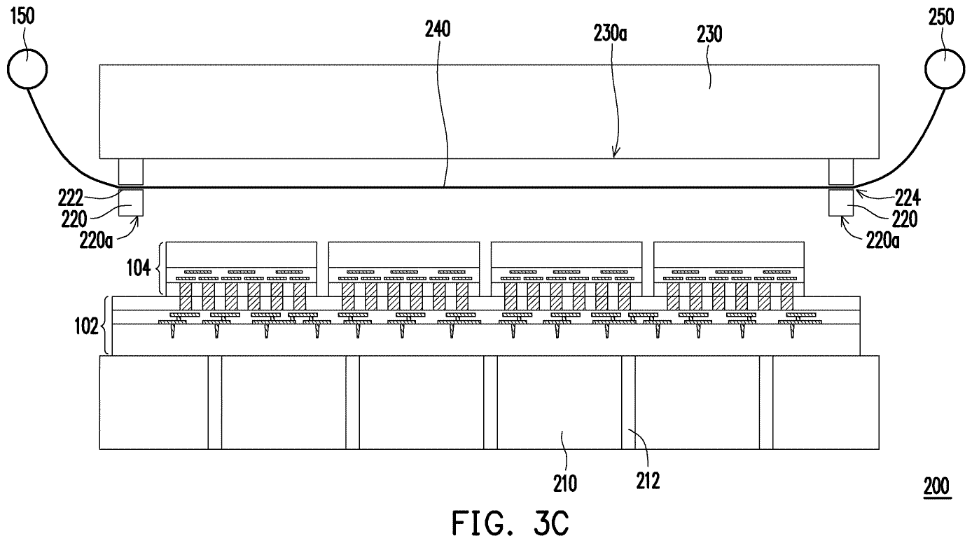

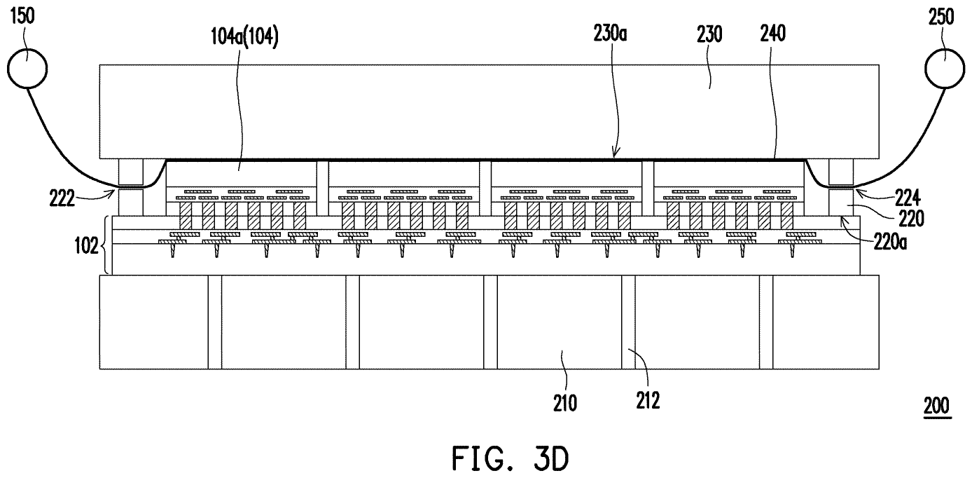

FIG. 3A through FIG. 3D schematically illustrating a CoW bonding process utilizing a bonding tool in accordance with some other embodiments of the present disclosure.

Referring to FIG. 3A, a semiconductor wafer 102 is provided. In some embodiments, the semiconductor wafer 102 includes semiconductor chips arranged in array, and the semiconductor chips in the semiconductor wafer 102 may be logic dies, System-on-Chip (SoC) dies or other suitable semiconductor dies. The semiconductor wafer 102 may include a substrate 102a (e.g., a semiconductor substrate), through substrate vias 102b embedded in the substrate 102a, an interconnect structure 102c disposed on the substrate 102a, and a bonding structure 102d disposed on the interconnect structure 102c, wherein the through substrate vias 102b are electrically connected to the interconnect structure 102c. The substrate 102a of the semiconductor wafer 102 may include a crystalline silicon wafer. The substrate 102a may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 102a may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The through substrate vias 102b may be formed by forming recesses in the substrate 102a by, for example, etching, milling, laser techniques, a combination thereof, and/or the like. A thin barrier layer may be conformally deposited over the front side of the substrate 102a and in the openings, such as by chemical vapor deposition (CVD), atomic layer deposition (ALD), physical vapor deposition (PVD), thermal oxidation, a combination thereof, and/or the like. The barrier layer may include a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the substrate 102a by, for example, chemical mechanical polishing (CMP). Thus, in some embodiments, the through substrate vias 102b may include a conductive material and a thin barrier layer between the conductive material and the substrate 102a. In some embodiments, the through substrate vias 102b may extend through one or more layers of the interconnect structure 102b and protrude into the substrate 102a. The through substrate vias 102b may be buried in the substrate 102a and the interconnect structure 102c of the semiconductor wafer 102. The through substrate vias 102b are not revealed from a back surface of the substrate 102a at this stage.

The interconnect structure 102c may include one or more dielectric layers (for example, one or more interlayer dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the substrate 102a. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof.

The bonding structure 102d may include a bonding dielectric layer 102d1 and bonding conductors 102d2 embedded in the bonding dielectric layer 102d1. The material of the bonding dielectric layer 102d1 may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 102d2 may be conductive vias (e.g., copper vias), conductive pads (e.g., copper pads) or combinations thereof. The bonding structure 102d may be formed by depositing a dielectric material through a chemical vapor deposition (CVD) process (e.g., a plasma enhanced CVD process or other suitable process); patterning the dielectric material to form the bonding dielectric layer 102d1 including openings or through holes; and filling conductive material in the openings or through holes defined in the bonding dielectric layer 102d1 to form the bonding conductors 102d2 embedded in the bonding dielectric layer 102d1.

In some other embodiments, the semiconductor wafer 102 includes a semiconductor interposer, such as a silicon interposer or other suitable semiconductor interposer. In some alternative embodiments, the semiconductor wafer 102 includes a reconstructed wafer, and the reconstructed wafer may include semiconductor chips arranged in side-by-side manner and laterally encapsulated by an insulating encapsulant.

As illustrated in FIG. 3A, the semiconductor wafer 102 is placed on and held by a wafer chuck 210. The wafer chuck 210 may include vacuum suctions 212 communicated with a vacuum extraction machine (not shown) such that the semiconductor wafer 102 can be carried by the wafer chuck 210 stably.

Referring to FIG. 3B, semiconductor dies 104 are provided over the semiconductor wafer 102 carried by the wafer chuck 210. The semiconductor dies 104 and the semiconductor chips in the semiconductor wafer 102 may perform the same function or different functions. In some embodiments, the semiconductor dies 104 and the semiconductor chips in the semiconductor wafer 102 are System on Chip (SoC) dies performing the same function or different functions.

Each of the semiconductor dies 104 may include a substrate 104a (e.g., a semiconductor substrate), an interconnect structure 104b disposed on the substrate 104a, and a bonding structure 104c disposed on the interconnect structure 104b. The substrate 104a of each of the semiconductor dies 104 may include a crystalline silicon wafer. The substrate 104a may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 104a may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The interconnect structure 104b may include one or more dielectric layers (for example, one or more interlayer dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the substrate 104a. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof.

The bonding structure 104c may include a bonding dielectric layer 104c1 and bonding conductors 104c2 embedded in the bonding dielectric layer 104c1. The material of the bonding dielectric layer 104c1 may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 104c2 may be conductive vias (e.g., copper vias), conductive pads (e.g., copper pads) or combinations thereof. The bonding structure 104c may be formed by depositing a dielectric material through a chemical vapor deposition (CVD) process (e.g., a plasma enhanced CVD process or other suitable process); patterning the dielectric material to form the bonding dielectric layer 104c1 including openings or through holes; and filling conductive material in the openings or through holes defined in the bonding dielectric layer 104c1 to form the bonding conductors 104c2 embedded in the bonding dielectric layer 104c1.

Referring to FIG. 3C, through proper alignment, the semiconductor dies 104 are picked-up and placed onto the semiconductor wafer 102. After the semiconductor dies 104 are picked-up and placed onto the semiconductor wafer 102, a hard plate 230, a buffer layer 240 carried by the hard plate 230, and an edge support 220 disposed on the bottom surface 230a of the hard plate 230 are provided over the semiconductor dies 104 and the semiconductor wafer 102 carried by the wafer chuck 210.

In some embodiments, the edge support 220 is fastened on the bottom surface 230a of the hard plate 230 through, for example, screws or other suitable fastening elements such that the bottom surface 220a of the edge support 220 is vertically spaced apart from the semiconductor wafer 102. In some embodiments, the edge support 220 includes a ring-shaped support structure, and the edge support 220 is laterally as well as vertically spaced apart from the semiconductor dies 104. As illustrated in FIG. 3C, the edge support 220 includes a feed-in channel 222 and a feed-out channel 224. The buffer layer 240 penetrates through the feed-in channel 222 and the feed-out channel 225 such that the buffer layer 240 is fed between the hard plate 230 and the semiconductor dies 104.

The material of the hard plate 230 may be or include polyetheretherketone (PEEK), polyimide or other suitable plastic materials. The buffer layer 240 may be or include a release film or other flexible and buffer film. The buffer layer 240 is provided between the hard plate 230 and the semiconductor dies 104. At this stage, the buffer layer 240 is vertically spaced apart from the hard plate 230 and the semiconductor dies 104. The buffer layer 240 may be applied or fed by a group of rollers 250 such that the buffer layer 240 can be fed between the hard plate 230 and the semiconductor dies 104. The buffer layer 240 is capable of minimizing the Total Thickness Variation (TTV) issue of the semiconductor dies 104 during the subsequently performed Chip-to-Wafer (CoW) bonding process. The group of rollers 250 are capable of driving the movement of the buffer layer 240 such that different regions of the buffer layer 240 can be utilized to minimize the TTV issue of the semiconductor dies 104 during the subsequently performed Chip-to-Wafer (CoW) bonding process.

Referring to FIG. 1C and FIG. 1D, after the semiconductor dies 104 are picked-up and placed onto the semiconductor wafer 102, the hard plate 330 and the edge support 220 are driven to move towards the wafer chuck 210 such that the buffer layer 240 can move downwardly until the buffer layer 240 is in contact with the surfaces (e.g., the back surfaces) of the semiconductor dies 104 and the bottom surface 220a of the edge support 220 is in contact with the semiconductor wafer 102. After the buffer layer 240 is pressed onto the surfaces (e.g., the back surfaces) of the semiconductor dies 104 as well as the bottom surface 220a of the edge support 220 is in contact with the semiconductor wafer 102, a gap between the hard plate 230 and the semiconductor wafer 102 is maintained by the edge support 220 disposed under the hard plate 230. For example, the gap between the hard plate 230 and the semiconductor wafer 102 is maintained by the edge support 220 disposed on the semiconductor wafer 102 after the buffer layer 240 is pressed onto the semiconductor dies 104. As illustrated in FIG. 3D, at this stage, the semiconductor dies 104 are laterally surrounded by the edge support 220.

After the buffer layer 240 is pressed onto the surfaces (e.g., the back surfaces) of the semiconductor dies 104, an annealing process is performed such that the bonding structures 104c of the semiconductor dies 104 are in contact with and bonded to the bonding structure 102d of the semiconductor wafer 102. After performing the annealing process, a chip-to-wafer (CoW) bonding process of the semiconductor dies 104 and the semiconductor wafer 102 is accomplished.

After performing the above-mentioned chip-to-wafer (CoW) bonding process, a dielectric-to-dielectric bonding interface is formed between the bonding dielectric layer 104c1 and the bonding dielectric layer 102d1, and metal-to-metal bonding interfaces are formed between the bonding conductors 104c2 and bonding conductors 102d2.

After the semiconductor dies 104 are bonded to the semiconductor wafer 102, a chip probing process may be performed to increase yields.

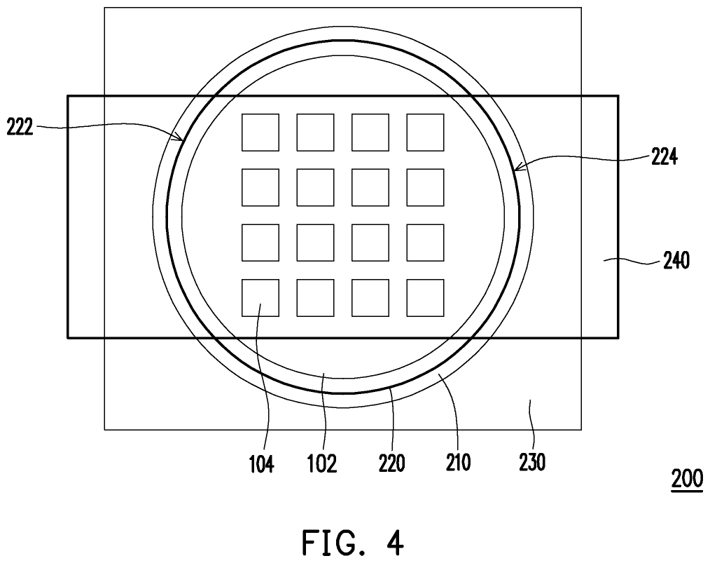

FIG. 4 is a top view schematically illustrating the relationship of the edge support, the semiconductor wafer, the hard plate, and wafer chuck shown in FIG. 3A through FIG. 3D.

Referring to FIG. 4, As illustrated in FIG. 1C, FIG. 1D and FIG. 2, a bonding tool 200 for bonding semiconductor dies 104 to a semiconductor wafer 102 is provided. The bonding tool 200 of the present embodiment includes a hard plate 230, an edge support 220, and a buffer layer 240. The hard plate 230 is movably disposed over the semiconductor dies 104. The edge support 220 is disposed on a bottom surface 230a of the hard plate 230, and the edge support 220 includes a feed-in channel 222 and a feed-out channel 224. The buffer layer 240 penetrates through the feed-in channel 222 and the feed-out channel 224 such that the buffer layer 240 is fed between the hard plate 230 and the semiconductor dies 104, wherein the buffer layer 240 is in contact with the semiconductor dies 104 and the hard plate 230 when the hard plate 230 and the edge support 220 move towards the semiconductor wafer 102. In some embodiments, the bonding tool 200 further includes a wafer chuck 210, wherein the wafer chuck 210 carries the semiconductor wafer 102 and the semiconductor dies 104 placed on the semiconductor wafer 102. In some embodiments, the wafer chuck 210 includes a circular-shaped chuck, and the hard plate 230 includes a circular-shaped hard plate. In some embodiments, the edge support 22 is disposed between the hard plate 230 and the semiconductor wafer 102. In some embodiments, the edge support 220 is in contact with the semiconductor wafer 102 when the hard plate 230 and the edge support 220 move towards the semiconductor wafer 102. In some embodiments, the edge support 220 includes a ring-shaped support structure, and the hard plate 230 includes a circular-shaped hard plate. In some embodiments, the diameter of the ring-shaped support structure 220 is smaller than the diameter of the circular-shaped hard plate 230. In some embodiments, the bonding tool 200 further includes a group of rollers 250 for feeding the buffer layer 240 between the hard plate 230 and the semiconductor dies 104.

In the above-mentioned bonding tool 100 or 200, the bonding force is vertically applied onto the semiconductor dies 104 and there is no lateral bonding force applied to the semiconductor dies 104. Accordingly, non-bonding issue occurred at corner regions of the semiconductor dies 104 may be minimized, and yields of the Chip-on-Wafer (CoW) bonding process of the semiconductor dies 104 and the semiconductor wafer 102 may increase.

In accordance with some embodiments of the disclosure, a bonding tool for bonding semiconductor dies to a semiconductor wafer is provided. The bonding tool includes a wafer chuck, an edge support, a hard plate, and a buffer layer. The wafer chuck carries the semiconductor wafer and the semiconductor dies placed on the semiconductor wafer. The edge support is disposed on the wafer chuck, the semiconductor wafer and the semiconductor dies are laterally surrounded by the edge support, and a top surface of the edge support substantially levels with surfaces of the semiconductor dies. The hard plate is movably disposed over the semiconductor dies, the edge support and the wafer chuck. The buffer layer is disposed on a bottom surface of the hard plate, and the buffer layer is in contact with the top surface of the edge support and the semiconductor dies when the hard plate moves towards the edge support. In some embodiments, the wafer chuck includes a circular-shaped chuck, and the hard plate includes a circular-shaped hard plate. In some embodiments, the edge support includes a ring-shaped support structure, and the edge support is laterally spaced apart from the semiconductor wafer. In some embodiments, the wafer chuck includes a circular-shaped chuck, and a diameter of the ring-shaped support structure is smaller than a diameter of the circular-shaped chuck. In some embodiments, the hard plate includes a circular-shaped hard plate, and a diameter of the ring-shaped support structure is smaller than a diameter of the circular-shaped hard plate. In some embodiments, a material of the hard plate includes polyetheretherketone (PEEK) or polyimide. In some embodiments, the buffer layer includes a release film. In some embodiments, the bonding tool further includes a group of rollers for feeding the buffer layer onto the bottom surface of the hard plate.

In accordance with some alternative embodiments of the disclosure, a bonding tool for bonding semiconductor dies to a semiconductor wafer is provided. The bonding tool includes a hard plate, an edge support, and a buffer layer. The hard plate is movably disposed over the semiconductor dies. The edge support is disposed on a bottom surface of the hard plate, and the edge support includes a feed-in channel and a feed-out channel. The buffer layer penetrates through the feed-in channel and the feed-out channel such that the buffer layer is fed between the hard plate and the semiconductor dies, wherein the buffer layer is in contact with the semiconductor dies and the hard plate when the hard plate and the edge support move towards the semiconductor wafer. In some embodiments, the bonding tool further includes a wafer chuck, wherein the wafer chuck carries the semiconductor wafer and the semiconductor dies placed on the semiconductor wafer. In some embodiments, the wafer chuck includes a circular-shaped chuck, and the hard plate includes a circular-shaped hard plate. In some embodiments, the edge support is disposed between the hard plate and the semiconductor wafer. In some embodiments, the edge support is in contact with the semiconductor wafer when the hard plate and the edge support move towards the semiconductor wafer. In some embodiments, the edge support includes a ring-shaped support structure, and the hard plate includes a circular-shaped hard plate. In some embodiments, a diameter of the ring-shaped support structure is smaller than a diameter of the circular-shaped hard plate. In some embodiments, the bonding tool further includes a group of rollers for feeding the buffer layer between the hard plate and the semiconductor dies.

In accordance with some other embodiments of the disclosure, a bonding process is provided. Semiconductor dies are placed onto a semiconductor wafer. A buffer layer is provided between a hard plate and the semiconductor dies. The hard plate is moved towards the semiconductor dies to press the buffer layer onto the semiconductor dies, wherein after the buffer layer is pressed onto the semiconductor dies, a gap between the hard plate and the semiconductor wafer is maintained by an edge support disposed under the hard plate. After the buffer layer is pressed onto the semiconductor dies, an annealing process is performed to bond the semiconductor dies onto the semiconductor wafer. In some embodiments, the gap between the hard plate and the semiconductor wafer is maintained by the edge support disposed on the semiconductor wafer after the buffer layer is pressed onto the semiconductor dies. In some embodiments, the semiconductor wafer is carried by a wafer chuck. In some embodiments, the gap between the hard plate and the semiconductor wafer is maintained by the edge support disposed on the wafer chuck after the buffer layer is pressed onto the semiconductor dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A bonding tool for bonding semiconductor dies to a semiconductor wafer, the bonding tool comprising:
a wafer chuck, wherein the wafer chuck carries the semiconductor wafer and the semiconductor dies placed on the semiconductor wafer;
an edge support disposed on the wafer chuck, wherein the semiconductor wafer and the semiconductor dies are laterally surrounded by the edge support, and a top surface of the edge support substantially levels with surfaces of the semiconductor dies;
a hard plate movably disposed over the semiconductor dies, the edge support and the wafer chuck; and
a buffer layer disposed on a bottom surface of the hard plate, wherein the buffer layer is in contact with the top surface of the edge support and the semiconductor dies when the hard plate moves towards the edge support.

2. The bonding tool of claim 1, wherein the wafer chuck comprises a circular-shaped chuck, and the hard plate comprises a circular-shaped hard plate.

3. The bonding tool of claim 1, wherein the edge support comprises a ring-shaped support structure, and the edge support is laterally spaced apart from the semiconductor wafer.

4. The bonding tool of claim 3, wherein the wafer chuck comprises a circular-shaped chuck, and a diameter of the ring-shaped support structure is smaller than a diameter of the circular-shaped chuck.

5. The bonding tool of claim 3, wherein the hard plate comprises a circular-shaped hard plate, and a diameter of the ring-shaped support structure is smaller than a diameter of the circular-shaped hard plate.

6. The bonding tool of claim 1, wherein a material of the hard plate comprises polyetheretherketone (PEEK) or polyimide.

7. The bonding tool of claim 1, wherein the buffer layer comprises a release film.

8. The bonding tool of claim 1 further comprising a group of rollers for feeding the buffer layer onto the bottom surface of the hard plate.

9. A bonding tool for bonding semiconductor dies to a semiconductor wafer, the bonding tool comprising:
a wafer chuck comprising a surface on which the semiconductor wafer and the semiconductor dies are placed;
a hard plate movably disposed over the wafer chuck;
an edge support disposed on the surface of the wafer chuck; and
a buffer layer delivered between the hard plate and the semiconductor dies, wherein the buffer layer is pressed onto and in contact with the semiconductor dies and the edge support when the hard plate moves toward the wafer chuck and the edge support.

10. The bonding tool of claim 9 further comprising:
a group of rollers for delivering the buffer layer to a place between the hard plate and the semiconductor dies.

11. The bonding tool of claim 9, wherein the wafer chuck comprises a circular-shaped chuck, and the hard plate comprises a circular-shaped hard plate.

12. The bonding tool of claim 9, wherein the edge support is between the hard plate and the wafer chuck when the buffer layer is pressed onto and in contact with the semiconductor dies and the edge support.

13. The bonding tool of claim 9, wherein the edge support is not in contact with the semiconductor wafer when the buffer layer is pressed onto and in contact with the semiconductor dies and the edge support.

14. The bonding tool of claim 9, wherein the edge support comprises a ring-shaped support structure, and the hard plate comprises a circular-shaped hard plate.

15. The bonding tool of claim 14, wherein a diameter of the ring-shaped support structure is smaller than a diameter of the circular-shaped hard plate.

16. A bonding process, comprising:
placing semiconductor dies onto a semiconductor wafer carried by a wafer chuck, wherein the wafer chuck comprises an edge support;
providing a buffer layer between a hard plate and the semiconductor dies;
moving the hard plate towards the semiconductor dies to press the buffer layer onto the semiconductor dies, wherein a gap between the hard plate and the wafer chuck is maintained by the edge support after the buffer layer is pressed onto the semiconductor dies; and
after the buffer layer is pressed onto the semiconductor dies, performing an annealing process to bond the semiconductor dies to the semiconductor wafer.

17. The bonding process of claim 16, wherein the edge support is laterally spaced apart from the semiconductor wafer when the buffer layer is pressed onto the semiconductor dies.

18. The bonding process of claim 16, wherein the buffer layer is pressed onto the edge support when moving the hard plate towards the semiconductor dies to press the buffer layer onto the semiconductor dies.

19. The bonding process of claim 16 further comprising a vacuum extraction machine, wherein the wafer chuck comprises vacuum suctions communicated with the vacuum extraction machine.

20. The bonding process of claim 16, wherein a top surface of the edge support substantially levels surfaces of the semiconductor dies after placing the semiconductor dies onto the semiconductor wafer carried by the wafer chuck.
